(19) United States
(12) Patent Application Publication
(10) Pub. No.: US 2026/0040977 A1
(43) Pub. Date: Feb. 5, 2026

(54) PANEL-LEVEL FORMATION OF LOGIC-UPPERMOST SEMICONDUCTOR DEVICE ASSEMBLIES WITH MULTI-RETICLE DIES AND RETICLE-BRIDGING CONDUCTORS

(71) Applicant: Micron Technology, Inc., Boise, ID (US)

(72) Inventors: Bharat Bhushan, Singapore (SG); Kunal R. Parekh, Boise, ID (US); Akshay N. Singh, Boise, ID (US); Ameen D. Akel, Rancho Cordova, CA (US)

(21) Appl. No.: 19/281,210

(22) Filed: Jul. 25, 2025

Related U.S. Application Data
(60) Provisional application No. 63/677,987, filed on Jul. 31, 2024.

(51) Int. Cl. H01L 23/538; H01L 21/48; H01L 23/00; H01L 23/13; H01L 23/14; H01L 23/24; H01L 23/48; H01L 25/18; H10B 80/00; H10D 80/30

(52) U.S. Cl. CPC H01L 23/5386; H01L 21/486; H01L 23/13; H01L 23/147; H01L 23/24; H01L 23/481; H01L 23/5385; H01L 25/18; H10B 80/00; H10D 80/30; H01L 24/08; H01L 24/80; H01L 2224/08145; H01L 2224/80895; H01L 2224/80896; H01L 2225/06524; H01L 2225/06544

(57) ABSTRACT

A semiconductor device assembly comprises an RDL including an external surface with external contacts, an internal surface with internal contacts, and conductors coupling the internal contacts to the external contacts. The assembly further includes a device connection layer having a first surface with first contact pads, a second surface with second contact pads, first conductive structures electrically coupling each of the first contact pads to a corresponding second contact pad, and a second plurality of conductive structures electrically coupling each of a first subset of the second plurality of contact pads to a corresponding contact pad of a second subset of the second plurality of contact pads. The assembly further includes stacks of semiconductor devices disposed between the RDL and the device connection layer, each stack in a cavity in a monolithic glass structure. The stacks electrically couple internal contacts to the first contact pads through TSVs in the stacks.

### CROSS-REFERENCE TO RELATED APPLICATION(S)

The present application claims priority to U.S. Provisional Patent Application No. 63/677,987, filed Jul. 31, 2024, the disclosure of which is incorporated herein by reference in its entirety.

### TECHNICAL FIELD

The present disclosure generally relates to semiconductor device assemblies, and more particularly relates to panel-level formation of logic-uppermost semiconductor device assemblies with multi-reticle dies and reticle-bridging conductors.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIGS. 1 through 6 are simplified schematic cross-sectional views of different stages of the manufacturing process of an example semiconductor device assembly in accordance with embodiments of the present technology.

FIG. 7 is a simplified schematic cross-sectional view of a semiconductor device assembly in accordance with embodiments of the present technology.

FIG. 8 is a simplified schematic partial plan view of a semiconductor device assembly in accordance with embodiments of the present technology.

FIG. 9 is a flow chart illustrating a method of making a semiconductor device assembly in accordance with an embodiment of the present technology.

FIG. 10 is a schematic view showing a system that includes a semiconductor device assembly configured in accordance with an embodiment of the present technology.

### DETAILED DESCRIPTION

The demand for greater performance from semiconductor devices appears to be insatiable. To increase the performance of a device, more features can be included in a device of given size by shrinking the feature dimensions through lithography improvements. As feature shrink nears theoretical limits, however, adding more features has driven an increase in the size (i.e., footprint) of semiconductor devices. With the footprint of semiconductor devices increasing up to the limit of lithographic reticle size (a limit which would require dramatic re-tooling of an entire industry to overcome), increasing the capability of semiconductor devices may be accomplished by integrating multiple reticle-limited semiconductor devices into a single assembly.

Reticle-limited semiconductor devices have a footprint greater than the size of a single reticle field (e.g., current EUV reticle sizes are limited to about 858 mm²) and include multiple reticle-sized circuit areas that, due to the limitations of accurately aligning two different reticle fields, may be spaced apart from one another by a region of un-patterned silicon substrate with no conductors or other circuit features therein (e.g., resembling two discrete dies in an un-singulated portion of a semiconductor wafer). Unlike two discrete dies in an un-singulated portion of semiconductor substrate, however, in a reticle-limited semiconductor device the multiple reticle-limited circuit areas may not be designed identically, however, and may include features intended to connected to each other across the un-patterned region of the substrate (e.g., by subsequent BEOL metallization or by connected to an interposer).

A challenge with these approaches to coupling the discrete circuit regions of a multi-reticle semiconductor device is the additional manufacturing cost, package size (e.g., from a dedicated interposer with solder bond line) and increased circuit path length (e.g. interposed between the multi-reticle semiconductor device and its host and/or between the multi-reticle semiconductor device and auxiliary devices integrated with it, such as memory). To solve these drawbacks and others, embodiments of the present disclosure provide semiconductor device assemblies with a prefabricated device connection layer that can be directly bonded, in a panel-level operation, to a multi-reticle semiconductor device. The device connection layer can couple not only the discrete circuit regions of the multi-reticle semiconductor device to each other, but also the multi-reticle semiconductor device to other semiconductor devices in a heterogenous device assembly, such as memory, as well as to external package contacts (e.g., by conductive paths extending through the other semiconductor devices in the assembly).

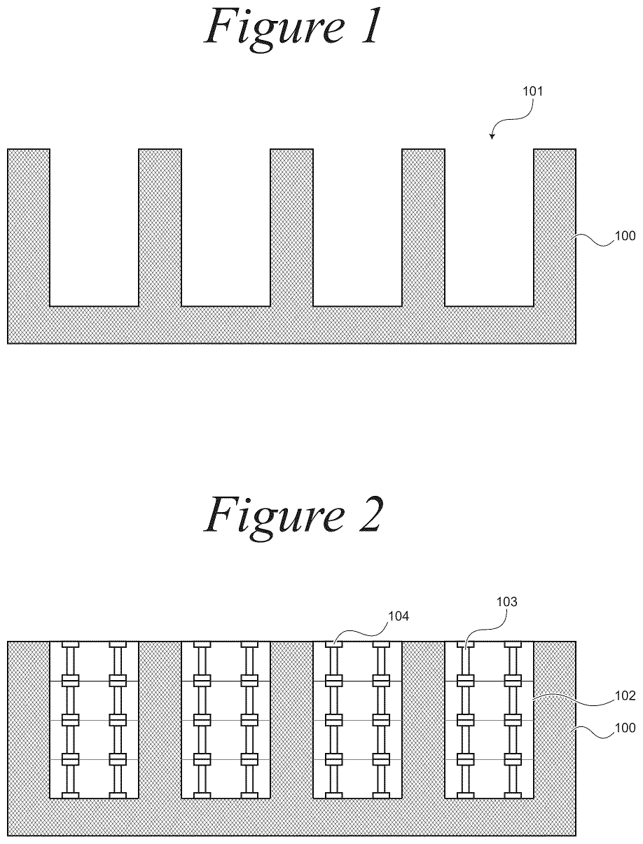

FIGS. 1 through 6 are simplified schematic cross-sectional views of different stages of the manufacturing process of an example semiconductor device assembly in accordance with embodiments of the present technology. Turning to FIG. 1, multiple cavities 101 are formed in a glass substrate 100 (e.g., a glass substrate, a glass panel, etc.). In FIG. 2, stacks 102 of memory devices are disposed in the cavities. The stacks can include 2, 4, 6, 8, 12, 16, or 24 stacks of memory devices. It may also include a controller die/MIB/DPL at the top of the stack. These stacks can be formed using chip-to-chip (C2C), singulated after wafer-to-wafer (W2 W), or chip-to-wafer (C2 W) techniques. The memory devices include contact structures 104 and TSVs 103 for forming interconnects with additional devices in a wafer-level or panel-level hybrid bonding process. For example, the panel or wafer's bottom surface can be removed (e.g. by grinding) at least to the point of exposing the bottom DRAM dies' contact structure. Then, a dielectric material can be disposed of on the surface, followed by a μ-bump formation process. The stacks 102 are surrounded and separated by the glass material of the panel or wafer.

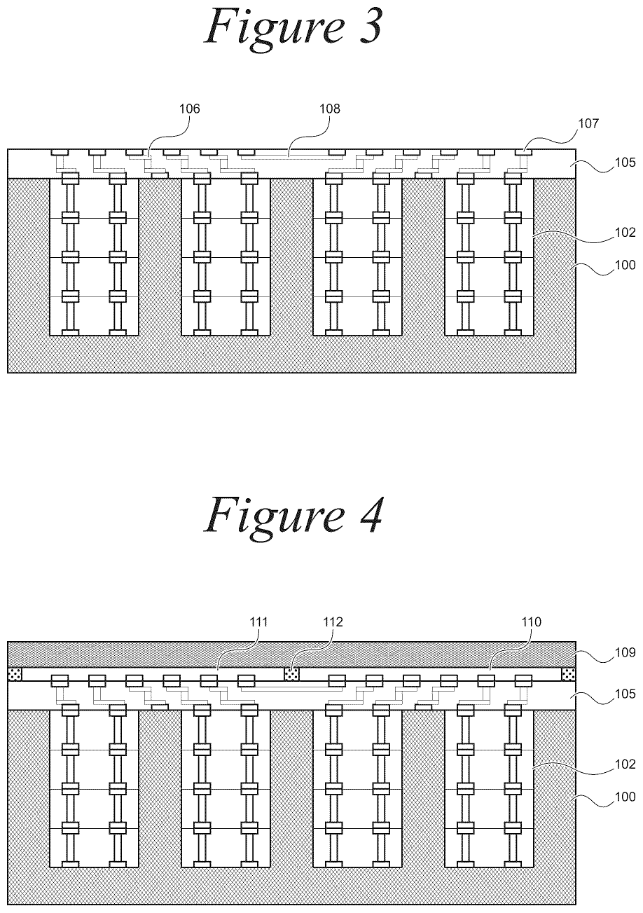

As is illustrated in FIG. 3, a device connection layer 105 can be formed over the stacks 102 and the glass substrate 100. The device connection layer 105 can be formed like a redistribution layer, with back end of line (BEOL) metallization processes well known to those of skill in the art. For example, the layer can be formed using RDL/iRDL processes, including a single damascene process or a dual damascene process. For example, iteratively depositing and patterning dielectric material, and plating metal such as copper into the patterned openings in the dielectric material, permits the construction of metal contacts 107 both facing (and coupled to) the exposed contacts 104 of the stacks 102 and outwardly from the stacks, as well as the conductive metal structures 106 that couple the contacts 107 on the stack-facing (i.e., lower in the orientation of FIG. 3) side of the device connection layer 105 to contacts 107 on the outwardly-facing (i.e., upper in the orientation of FIG. 3) side of the device connection layer 105. The contacts 107 on the outwardly facing side of the device connection layer 105 include a subset that are not coupled to stack-facing contacts but are rather coupled by reticle-bridging conductors 108 (one pair is shown in the cross-sectional view of FIG. 4, additional pairs of the subset are illustrated in FIG. 8, below). The reticle-bridging conductors 108 (which may be forme dby exposing the middle/bridge portion of the die to a different reticle to pattern and further develop traces and pads connecting the reticle-limited regions) can provide inter-region connectivity to a multi-reticle semiconductor device with multiple discrete circuit regions, as shown and described in greater detail below.

Turning to FIG. 4, a substrate 109 (e.g., a panel) carrying a multi-reticle semiconductor device with two discrete reticle-limited circuit regions 110 and 111 (e.g., in various embodiments, GPUs, CPUs, or the like) has been hybrid-bonded (i.e., with a dielectric-dielectric bond in regions without conductive contacts, and with a solder-free direct metal-metal bond in regions where contacts of the circuit regions 110 and 111 align with the contacts 107 of the device connection layer 105) to the device connection layer 105. Because of the reticle-limited size of the circuit regions 110 and 111, there are no conductors disposed within the region separating them, and prior to bonding them to the device connection layer 105, the circuit regions 110 and 111 are electrically isolated from one another. After the bonding operation however, reticle-bridging conductors 108 operably couple contacts from one circuit area 110 to the other 111, providing inter-region connectivity and permitting the multi-reticle semiconductor device to function as a single integrated device.

In accordance with one aspect of the present disclosure, the plurality of circuit regions may be horizontally spaced apart from one another by a reticle-edge region 112 does not include any electrical conductors (e.g., due to the limitations imposed by the maximum size of a photolithography reticle). In one embodiment, the reticle edge region 112 may be a continuous body of silicon shared by the circuit regions 110 and 111 (e.g., when the circuit regions 110 and 111 are formed in a common wafer and not singulated apart from one another). In this regard, substrate 109 may be a glass panel with cavities sized to accommodate a multi-reticle semiconductor device with multiple circuit regions 110 and 111 that have not been singulated from one another. In another embodiment, substrate 109 may have separate reticle-limited device that are singulated from one another mounted thereon and spaced horizontally apart from one another by a gap fill material comprised by the reticle edge region 112 (e.g., silicon oxide, silicon nitride, or mold material). In yet another embodiment, cavities in a glass substrate 109 may be sized to accommodate separate (e.g., singulated) circuit regions 110 and 111.

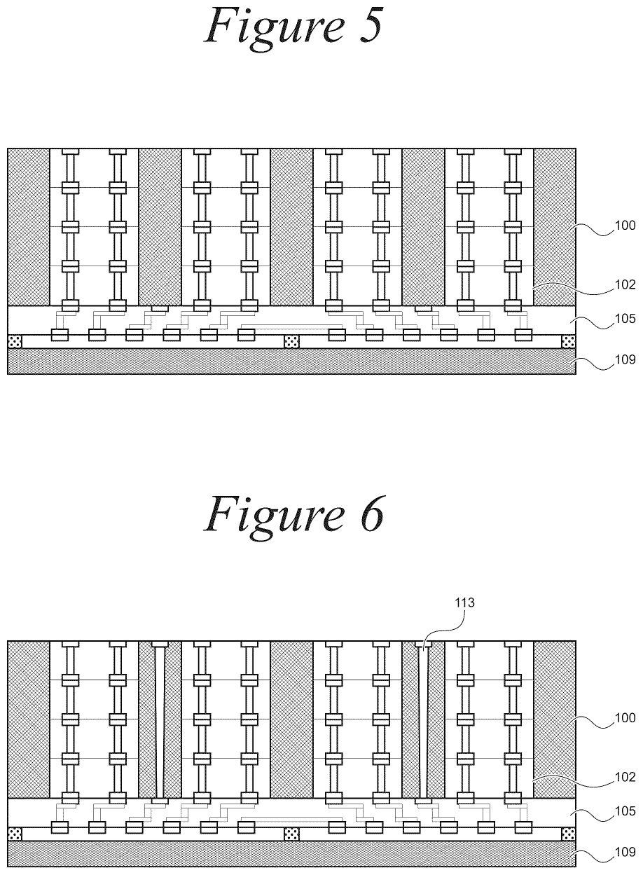

Turning to FIG. 5, glass substrate 100 is illustrated after having been thinned to expose stacks 102 and the contacts 104 at an upper surface thereof for further processing. The glass substrate 100 may be thinned by any one of a number of processes known to those of skill in the art, including grinding, polishing, fly cutting, etc. In accordance with another aspect of the present disclosure, after exposing the stacks 102 the assembly illustrated in FIG. 5 can be modified to include through-glass vias for connecting additional layers directly to the device connection layer 110, so that signals (e.g., i/o, ground, power, etc.) can be directly provided to the multi-reticle semiconductor device without connecting to circuit elements of the semiconductor devices (e.g., memory devices) positioned therebetween. The through-glass vias 113, as illustrated in FIG. 6, may be formed by etching an opening aligned with the contact structures 107 of the device connection layer 105 and plating a conductive metal (e.g., copper, tungsten, etc.) into the opening. The process may be a dual-damascene process, such as is commonly used to form vias with integrated contact pads. Due to the aspect ratio of the etching operation, a continuous taper from one end to the other of the through-glass vias 113 may be observed.

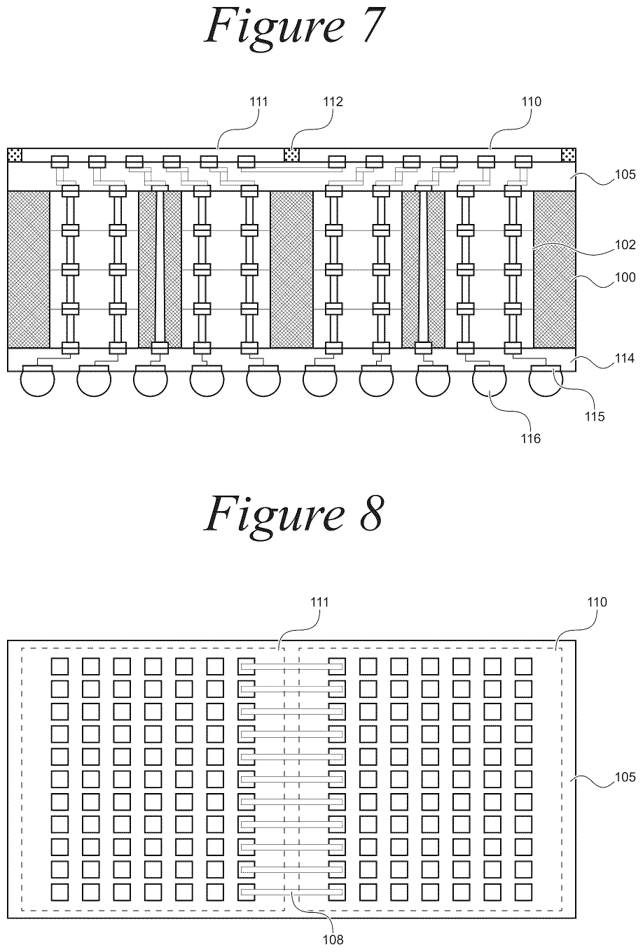

Turning to FIG. 7, after thinning the glass substrate 100, a redistribution layer (RDL) 114 can be formed over the stacks 102 and the thinned substrate 100. The RDL 114 can be formed with back end of line (BEOL) metallization processes well known to those of skill in the art. For example, iteratively depositing and patterning dielectric material, and plating metal such as copper into the patterned openings in the dielectric material, permits the construction of external contacts 115 and internal contacts (not labeled), as well as the conductive metal structures that couple the internal contacts and external contacts 115 to each other. Solder balls 116 can be formed on the external contacts 115 of RDL 114 for connection to higher-level devices, and the substrate can also be singulated at this point, such that the sidewalls illustrated in the Figure correspond to exterior surfaces of the singulated device.

Turning to FIG. 8, a simplified schematic partial plan view of a semiconductor device assembly in accordance with embodiments of the present technology illustrates additional details of the device connection layer 105. As can be seen with reference to FIG. 8, device connection layer 105 includes multiple reticle-bridging conductors 108 arranged to electrically connect pair of contacts 107 associated with the discrete reticle-limited circuit areas 110 and 111 of the multi-reticle semiconductor device. Although in the present example embodiment, a multi-reticle semiconductor device is illustrated and described as including two discrete circuit areas 110 and 111, in other embodiments a multi-reticle semiconductor device can include more than two circuit areas, and the reticle bridging conductors 108 of the device connection layer 105 may couple contacts 107 to one another in a one-to-one, a one-to-many, and/or a many-to-many topology, as may be desirable for different multi-reticle semiconductor device designs.

Although in the foregoing example embodiments semiconductor device assemblies have been illustrated with two stacks of memory devices on a single multi-reticle semiconductor device, in other embodiments greater or lesser numbers of stacks may be provided over a multi-reticle semiconductor device. Moreover, memory devices so provided may comprise a single type of memory, (e.g., NAND or DRAM or PCM or SRAM or MRAM, etc.) or a mixture of different types of memory (e.g., NAND and/or DRAM and/or PCM and/or SRAM and/or MRAM, etc.). Still further, although stacks have been illustrated with four memory devices vertically aligned, in other embodiments different stack heights may be implemented with fewer (e.g., one, two, or three) or more (e.g., five, six, eight, ten, twelve, etc.) layers of memory devices.

Although in the foregoing example embodiments, multi-reticle semiconductor device wafers have been illustrated as including multiple circuit areas in a continuous area of silicon, in other embodiments multi-reticle semiconductor devices can be provided in a reconstituted or heterogenous device wafer.

Although in the foregoing example embodiments semiconductor device assemblies have been illustrated with wafers facing the same direction (e.g., with active surfaces bonded to inactive surfaces), in other embodiments a stack of wafers may be bonded with active surfaces facing in different directions (or, mutatis mutandis, all facing the opposite way than illustrated, with back surfaces facing the external package contacts).

Although in the foregoing example embodiments semiconductor device assemblies have been illustrated with wafers bonded exclusively with a hybrid bonding approach, in other embodiments other wafer bonding approaches (e.g., solder interconnects) could be used in the alternative or additionally.

In accordance with one aspect of the present disclosure, the semiconductor devices illustrated in the assemblies of FIGS. 1-8 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, accelerator dies, etc.), or a mix of logic and memory dies (e.g., a memory controller die and a memory die controlled thereby).

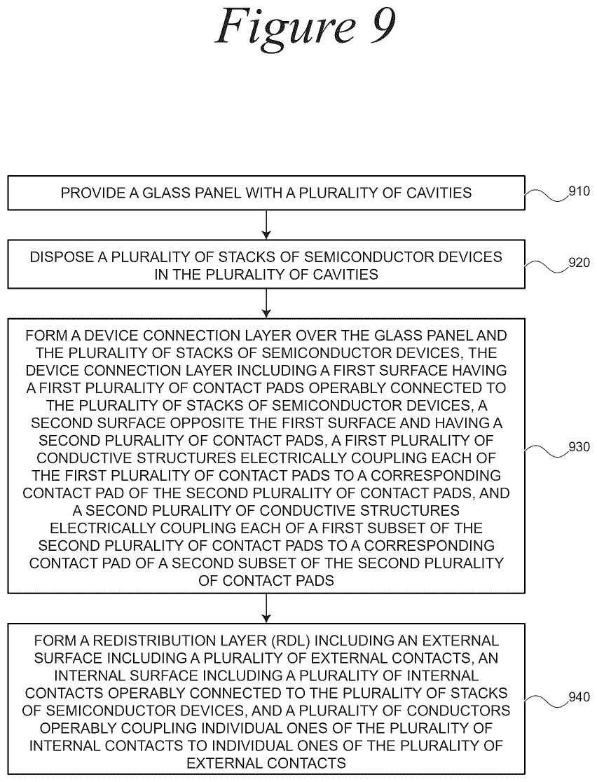

FIG. 9 is a flow chart illustrating a method of making a semiconductor device assembly. The method includes providing a glass substrate (e.g., a glass wafer or glass panel) with a plurality of cavities (box 910) and disposing a plurality of stacks of semiconductor devices in the plurality of cavities (box 920). The method further includes forming a device connection layer over the glass substrate and the plurality of stacks of semiconductor devices, the device connection layer including a first surface having a first plurality of contact pads operably connected to the plurality of stacks of semiconductor devices, a second surface opposite the first surface and having a second plurality of contact pads, a first plurality of conductive structures electrically coupling each of the first plurality of contact pads to a corresponding contact pad of the second plurality of contact pads, and a second plurality of conductive structures electrically coupling each of a first subset of the second plurality of contact pads to a corresponding contact pad of a second subset of the second plurality of contact pads (box 930). The method further includes forming a redistribution layer (RDL) including an external surface including a plurality of external contacts, an internal surface including a plurality of internal contacts operably connected to the plurality of stacks of semiconductor devices, and a plurality of conductors operably coupling individual ones of the plurality of internal contacts to individual ones of the plurality of external contacts (box 940).

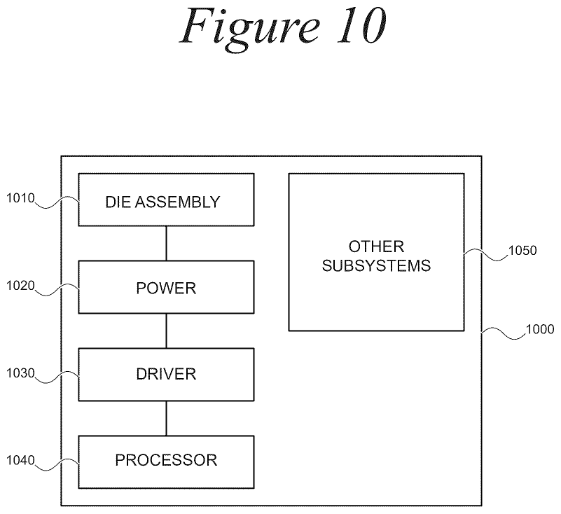

Any one of the semiconductor devices and semiconductor device assemblies described above with reference to FIGS. 1-8 can be incorporated into any of a myriad of larger and/or more complex systems, a representative example of which is system 1000 shown schematically in FIG. 10. The system 1000 can include a semiconductor device assembly (e.g., or a discrete semiconductor device) 1002, a power source 1004, a driver 1006, a processor 1008, and/or other subsystems or components 1010. The semiconductor device assembly 1002 can include features generally similar to those of the semiconductor devices described above with reference to FIGS. 1-8. The resulting system 1000 can perform any of a wide variety of functions, such as memory storage, data processing, and/or other suitable functions. Accordingly, representative systems 1000 can include, without limitation, hand-held devices (e.g., mobile phones, tablets, digital readers, and digital audio players), computers, vehicles, appliances and other products. Components of the system 1000 may be housed in a single unit or distributed over multiple, interconnected units (e.g., through a communications network). The components of the system 1000 can also include remote devices and any of a wide variety of computer readable media.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques. \

In other embodiments, the term “substrate” can refer to a package-level substrate upon which other semiconductor devices are carried, such as a printed circuit board (PCB), an interposer, or another semiconductor device.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a plurality of stacks of semiconductor devices, each stack disposed in a cavity in a monolithic glass structure, each stack of the plurality including multiple vertically-aligned semiconductor devices operably coupled by through-silicon vias (TSVs) to a plurality of external package contacts through a redistribution layer (RDL);
a device connection layer formed over the plurality of stacks of semiconductor devices and the monolithic glass structure, the device connection layer including a first plurality of contacts facing and coupled to the TSVs, a second plurality of contacts facing away from the TSVs, a first plurality of conductors operably coupling individual contacts of the first plurality to corresponding individual contacts of the second plurality, and a second plurality of conductors operably coupling individual contacts of the second plurality to other individual contacts of the second plurality; and
a multi-reticle semiconductor device disposed over the device connection layer, the multi-reticle semiconductor device including a plurality of circuit regions horizontally spaced apart from one another by a reticle-edge region absent any electrical conductors,
wherein the second plurality of conductors in the device connection layer operably interconnect the plurality of circuit regions.

2. The semiconductor device assembly of claim 1, wherein the reticle-edge region comprises a glass divider or a gap fill material.

3. The semiconductor device assembly of claim 1, wherein the reticle-edge region comprises a continuous body of silicon substrate material with the plurality of circuit regions.

4. The semiconductor device assembly of claim 1, wherein the second plurality of conductors extends horizontally under the reticle-edge region of the multi-reticle semiconductor device.

5. The semiconductor device assembly of claim 1, wherein:
the multi-reticle semiconductor device includes a first bonding surface including a first planar dielectric surface and a third plurality of contacts, and
the device connection layer includes a second bonding surface including a second planar dielectric surface and the second plurality of contacts, and
the first bonding surface and the second bonding surface are hybrid-bonded to one another such that the first planar dielectric surface and the second planar dielectric surface are bonded by a dielectric-dielectric bond and such that each of the second plurality of contact pads is bonded to a corresponding one of the third plurality of contact pads by a metal-metal bond exclusive of any solder.

6. The semiconductor device assembly of claim 1, further comprising a plurality of through-glass vias extending from the device connection layer to the RDL, each of the through-glass vias comprising a continuously tapering body of conductive metal.

7. The semiconductor device assembly of claim 6, wherein each through-glass via of the plurality of through-glass vias electrically couples the multi-reticle semiconductor device to an external package contact of the plurality of external package contacts exclusive of connection to any circuitry of the plurality of stacks of semiconductor devices.

8. A semiconductor device assembly, comprising:
a redistribution layer (RDL) including:
an external surface including a plurality of external contacts,
an internal surface including a plurality of internal contacts, and
a plurality of conductors operably coupling individual ones of the plurality of internal contacts to individual ones of the plurality of external contacts;
a device connection layer including:
a first surface having a first plurality of contact pads,
a second surface opposite the first surface and having a second plurality of contact pads,
a first plurality of conductive structures electrically coupling each of the first plurality of contact pads to a corresponding contact pad of the second plurality of contact pads, and
a second plurality of conductive structures electrically coupling each of a first subset of the second plurality of contact pads to a corresponding contact pad of a second subset of the second plurality of contact pads; and
a plurality of stacks of semiconductor devices disposed between the RDL and the device connection layer, each stack disposed in a cavity in a monolithic glass structure, the plurality of stacks electrically coupling individual ones of the plurality of internal contacts to individual ones of the first plurality of contact pads through TSVs disposed in the plurality of stacks.

9. The semiconductor device assembly of claim 8, further comprising a plurality of through-glass vias extending from the device connection layer to the RDL, each of the through-glass vias comprising a continuously tapering body of conductive metal.

10. The semiconductor device assembly of claim 9, wherein each through-glass via of the plurality of through-glass vias electrically couples the multi-reticle semiconductor device to an external package contact of the plurality of external package contacts exclusive of connection to any circuitry of the plurality of stacks of semiconductor devices.

11. A method of making a semiconductor device assembly, comprising:
providing a glass panel with a plurality of cavities;
disposing a plurality of stacks of semiconductor devices in the plurality of cavities;
forming a device connection layer over the glass panel and the plurality of stacks of semiconductor devices, the device connection layer including a first surface having a first plurality of contact pads operably connected to the plurality of stacks of semiconductor devices, a second surface opposite the first surface and having a second plurality of contact pads, a first plurality of conductive structures electrically coupling each of the first plurality of contact pads to a corresponding contact pad of the second plurality of contact pads, and a second plurality of conductive structures electrically coupling each of a first subset of the second plurality of contact pads to a corresponding contact pad of a second subset of the second plurality of contact pads; and
forming a redistribution layer (RDL) including an external surface including a plurality of external contacts, an internal surface including a plurality of internal contacts operably connected to the plurality of stacks of semiconductor devices, and a plurality of conductors operably coupling individual ones of the plurality of internal contacts to individual ones of the plurality of external contacts.

12. The method of claim 11, further comprising bonding a second semiconductor device to the second surface of the device connection layer, wherein the second semiconductor device includes first and second circuit regions separated from one another by a reticle-edge region absent any electrical conductors, such that bonding the second semiconductor device to the semiconductor device sub-assembly electrically couples the first and second circuit regions to each other through the second plurality of conductive structures.

13. The method of claim 12, wherein bonding the second semiconductor device to the second surface of the device connection layer comprises forming a hybrid bond including dielectric-dielectric bonds and metal-metal bonds.

14. The method of claim 13, wherein the hybrid bond is exclusive of any solder material.

15. The method of claim 12, wherein bonding the second semiconductor device to the semiconductor device sub-assembly comprises a panel-level bonding operation.

16. The method of claim 11, further comprising forming through-glass vias extending from the RDL to the device connection layer, each of the through-glass vias comprising a continuously tapering body of conductive metal.
